(19) United States
(12) Patent Application Publication
(10) Pub. No.: US 2024/0170554 A1
(43) Pub. Date: May 23, 2024

(54) SEMICONDUCTOR DEVICE

(71) Applicant: SAMSUNG ELECTRONICS CO., LTD., Suwon-si (KR)

(72) Inventors: Hyojin Kim, Suwon-si (KR); Jinbum Kim, Suwon-si (KR); Sangmoon Lee, Suwon-si (KR); Dongwoo Kim, Suwon-si (KR); Sungmin Kim, Suwon-si (KR); Yongjun Nam, Suwon-si (KR); Ingeon Hwang, Suwon-si (KR)

(73) Assignee: SAMSUNG ELECTRONICS CO., LTD., Suwon-si (KR)

(21) Appl. No.: 18/511,553

(22) Filed: Nov. 16, 2023

(30) Foreign Application Priority Data
Nov. 17, 2022 (KR) 10-2022-0154352

(51) Int. Cl. H01L 29/423; H01L 29/06; H01L 29/08; H01L 29/66; H01L 29/775; H01L 29/786

(52) U.S. Cl. CPC H01L 29/42392; H01L 29/0673; H01L 29/0847; H01L 29/66545; H01L 29/775; H01L 29/78696

(57) ABSTRACT

A semiconductor device is provided. The semiconductor device includes: an active pattern extending in a first direction on a substrate; channel layers arranged on the active pattern; a gate structure crossing the active pattern, and surrounding the plurality of channel layers, the gate structure extending in a second direction that crosses the first direction; and source/drain regions provided on the active pattern on both sides of the gate structure, and including a first epitaxial layer connected to each of side surfaces of the channel layers, and a second epitaxial layer provided on the first epitaxial layer and having a composition different from that of the first epitaxial layer. Each of the side surfaces of the plurality of channel layers has a crystal plane of (111) or (100). The first epitaxial layer extends in the second direction and has a first thickness in the first direction that is substantially constant.

### CROSS-REFERENCE TO RELATED APPLICATION(S)

This application claims priority to Korean Patent Application No. 10-2022-0154352, filed on Nov. 17, 2022, in the Korean Intellectual Property Office, the disclosure of which is incorporated by reference herein in its entirety.

### BACKGROUND

The present disclosure relates to a semiconductor device.

In order to improve the degree of integration of semiconductor devices, the size of transistors may be reduced. However, this reduction in the size of the transistor may cause a short-channel effect. In order to mitigate this short-channel effect, a fin field effect transistor (FinFET) in which a gate electrode contacts three surfaces of a channel structure, a gate-all-around field effect transistor (FET) in which a gate electrode surrounds four sides of a channel structure and a nanosheet field effect transistor are being researched and developed.

### SUMMARY

Example embodiments provide a semiconductor device having improved manufacturing yield and reliability.

According to example embodiments, a semiconductor device includes: a substrate; an active pattern extending in a first direction on the substrate; a plurality of channel layers arranged on the active pattern and spaced apart from each other in a vertical direction perpendicular to an upper surface of the substrate; a gate structure crossing the active pattern, and surrounding the plurality of channel layers, the gate structure extending in a second direction that crosses the first direction; and source/drain regions provided on the active pattern on both sides of the gate structure, and including a first epitaxial layer connected to each of side surfaces of the plurality of channel layers, and a second epitaxial layer provided on the first epitaxial layer and having a composition different from that of the first epitaxial layer. Each of the side surfaces of the plurality of channel layers has a crystal plane of (111) or (100). The first epitaxial layer extends in the second direction and has a first thickness in the first direction that is substantially constant.

According to example embodiments, a semiconductor device includes: a substrate; a semiconductor channel on the substrate, the semiconductor channel having first and second side surfaces spaced apart from each other in a first direction, and third and fourth side surfaces spaced apart in a second direction that crosses the first direction; first and second source/drain regions respectively provided on the first and second side surfaces of the semiconductor channel; and a gate structure surrounding an upper surface and the third and fourth side surfaces of the semiconductor channel and extending in the second direction. Each of the first and second source/drain regions includes a first epitaxial layer provided on the first and second side surfaces of the semiconductor channel and having a composition different from that of the first epitaxial layer. The first epitaxial layer extends in the second direction and has a first thickness in the first direction that is substantially constant. A cross section of each of the first and second source/drain regions along the second direction has a rectangular shape.

According to example embodiments, a semiconductor device includes: a substrate having an upper surface that is a (110) crystal plane; a semiconductor channel on the substrate, the semiconductor channel having first and second side surfaces spaced apart from each other in a first direction, and third and fourth side surfaces spaced apart in a second direction that crosses the first direction; first and second source/drain regions respectively provided on the first and second side surfaces of the semiconductor channel, each of the first side and the second side of the semiconductor channel having a (111) crystal plane; and a gate structure surrounding an upper surface and the third and fourth side surfaces of the semiconductor channel, and extending in the second direction, the second direction of the substrate corresponding to a <112> crystal direction.

According to example embodiments, a semiconductor device includes: a substrate having an upper surface that is a (100) crystal plane; a semiconductor channel on the substrate, the semiconductor channel having first and second side surfaces spaced apart from each other in a first direction, and third and fourth side surfaces spaced apart in a second direction that crosses the first direction; first and second source/drain regions respectively provided on the first and second side surfaces of the semiconductor channel, each of the first side and the second side of the semiconductor channel having a (100) crystal plane; and a gate structure surrounding an upper surface and the third and fourth side surfaces of the semiconductor channel and extending in the second direction, the second direction of the substrate corresponding to a <100> crystal direction.

### BRIEF DESCRIPTION OF DRAWINGS

The above and other aspects, features, and advantages will be more apparent from the following description of example embodiments, taken in conjunction with the accompanying drawings, in which:

FIG. 1 is a plan view illustrating a semiconductor device according to an example embodiment.

FIG. 2 is a cross-sectional view of the semiconductor device of FIG. 1 taken along line I-I′.

FIGS. 3A and 3B are cross-sectional views of the semiconductor device of FIG. 1 taken along lines II1-II1′ and II2-II2′, respectively.

FIG. 4 is a partially enlarged view illustrating part “A1” of FIG. 1, and FIG. 5 is a partially enlarged view of a comparative example corresponding to FIG. 4.

FIG. 6 is a plan view illustrating a semiconductor device according to an example embodiment.

FIG. 7 is a cross-sectional view of the semiconductor device of FIG. 6 taken along line I-I′.

FIGS. 8A and 8B are cross-sectional views of the semiconductor device of FIG. 6 taken along lines II1-II1′ and II2-II2′, respectively.

FIG. 9 is a partially enlarged view illustrating part “A2” of FIG. 6.

FIGS. 10A, 10B, 10C and 10D are perspective views for explaining some processes (forming a fin structure and a dummy gate) of a method of manufacturing a semiconductor device according to an example embodiment.

FIGS. 11A, 11B, 11C, 11D and 11E are cross-sectional views for explaining part of a method of manufacturing a semiconductor device (formation of source/drain and gate structures) according to an example embodiment.

FIG. 12 is a plan view illustrating a semiconductor device according to an example embodiment.

FIG. 13 is a cross-sectional view of the semiconductor device of FIG. 12 taken along line I-I′.

FIGS. 14A and 14B are cross-sectional views of the semiconductor device of FIG. 12 taken along lines II1-II1′ and II2-II2′, respectively.

### DETAILED DESCRIPTION

Hereinafter, example embodiments will be described with reference to the accompanying drawings. Embodiments described herein are provided as examples, and thus, the present disclosure is not limited thereto, and may be realized in various other forms. Each example embodiment provided in the following description is not excluded from being associated with one or more features of another example or another example embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

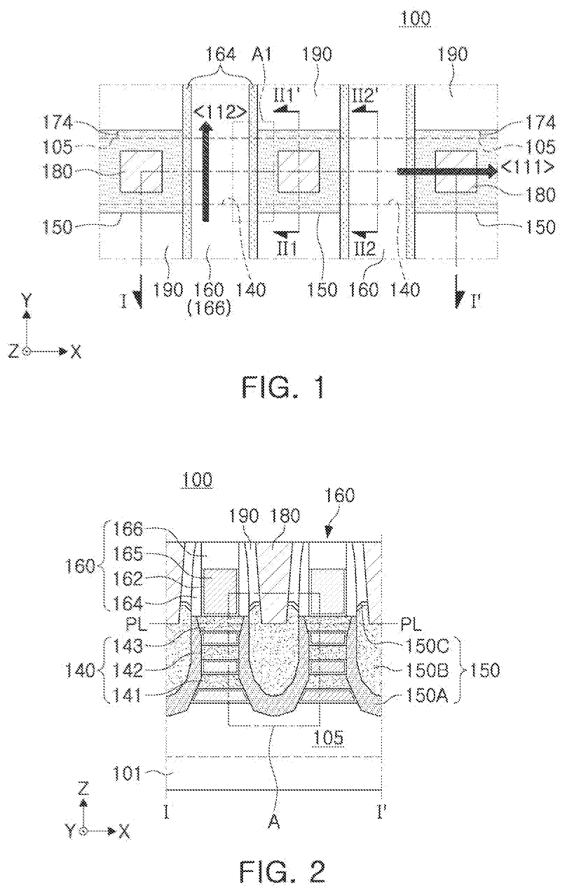

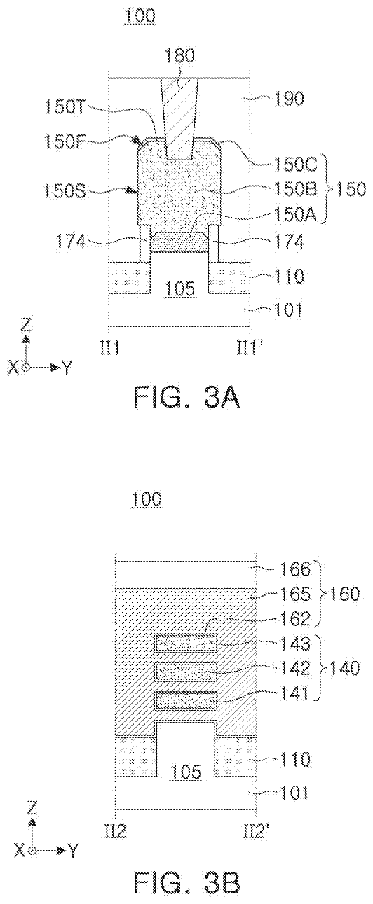

FIG. 1 is a plan view illustrating a semiconductor device according to an example embodiment, FIG. 2 is a cross-sectional view of the semiconductor device of FIG. 1 taken along line I-I′, and FIGS. 3A and 3B are cross-sectional views of the semiconductor device of FIG. 1 taken along lines II1-II1′ and II2-II2′, respectively.

Referring to FIGS. 1, 2, 3A, and 3B, a semiconductor device 100 according to example embodiments includes a substrate 101, an active pattern 105 protruding on the substrate 101 and extending in a first direction (e.g., the X-direction), a plurality of channel layers (141, 142, 143) disposed on the active pattern 105, and a gate structure 160 extending in a second direction (e.g., the Y-direction) crossing the active pattern 105. The plurality of channel layers 141, 142, and 143 may be spaced apart from each other on the active pattern 105 in a direction perpendicular to the top surface of the substrate 101 (e.g., the Z-direction).

The upper surface of the substrate 101 has a (110) crystal plane rotated by 35.3° with respect to an axis perpendicular to the upper surface, unlike the upper surface ((100) crystal plane) of a substrate implemented in related devices. For example, the substrate 101 may be a silicon substrate or a silicon on insulating (SOI) substrate. A first direction (e.g., the X-direction), a second direction (e.g., the Y-direction), and a third direction (e.g., Z-direction) may also be determined in terms of the crystal structure by the new selection of the top surface of the substrate 101. As illustrated in FIG. 1, the first direction (e.g., the X-direction) in which the active pattern 105 extends may be a <111> crystal direction, and the second direction in which the gate structure 160 extends (e.g., the Y-direction) may be a <112> crystal direction.

The active pattern 105 has a protruding fin structure, and the protruding fin structure extends in a first direction (e.g., the X-direction) corresponding to the <111> crystal direction. The device isolation layer 110 may define the active pattern 105. As illustrated in FIGS. 3A and 3B, the device isolation layer 110 may be disposed on the substrate 101 to cover the side surface of the active pattern 105 of the substrate 101. The device isolation layer 110 may include, for example, an oxide layer, a nitride layer, or a combination thereof. In some example embodiments, the device isolation layer 110 may include a deep trench isolation (DTI) region formed deeper than the STI to define an active region in which the fin structure is formed in addition to the shallow trench isolation (STI) region defining the active pattern 105.

The device isolation layer 110 may be formed to expose an upper region of the active pattern 105. In some example embodiments, the device isolation layer 110 may have a curved upper surface having a higher level as it is closer to the active pattern 105.

Referring to FIG. 3A, an upper region of the active pattern 105 may protrude from the upper surface of the device isolation layer 110. The active pattern 105 may include a portion of the substrate 101 or an epitaxial layer grown from the substrate 101. However, referring to FIG. 2, portions of the active patterns 105 on the substrate 101 located on both sides of the gate structures 160 are exposed, and source/drain regions 150 may be formed in the exposed regions. Details of the source/drain regions 150 will be described later.

As illustrated in FIGS. 1 and 2, the gate structure 160 extends in a second direction (e.g., the Y-direction) corresponding to the <112> crystal direction. The gate structure 160 includes a gate electrode 165 surrounding the plurality of channel layers 141, 142, and 143, a gate insulating layer 162 disposed between the gate electrode 165 and the plurality of channel layers 141, 142, and 143, gate spacers 164 disposed on side surfaces of the gate electrode 165 and a gate capping layer 166 disposed on the gate electrode 165.

In this manner, the semiconductor device 100 according to example embodiments may be a gate-all-around (Gate-All-Around) field effect transistor (FET) (e.g., P-MOS transistor) including a plurality of channel layers 141, 142 and 143, source/drain regions 150, and gate structures 160.

In example embodiments, the first to third channel layers 141, 142, and 143 may be spaced apart from each other in a third direction (e.g., Z-direction) perpendicular to the top surface of the substrate 101 on the active pattern 105. Both side surfaces of the first to third channel layers 141, 142, and 143 in the first direction (X-direction) may contact the source/drain region 150.

As shown in FIGS. 2 and 3A, the source/drain region 150 includes a first epitaxial layer 150A and a second epitaxial layer 150B on the first epitaxial layer 150A. The source/drain region 150 may further include a third epitaxial layer 150C on the second epitaxial layer 150B. The first to third epitaxial layers 150A, 150B, and 150C may have different compositions. For example, the first and second epitaxial layers 150A and 150B may include at least one of silicon (Si), silicon germanium (SiGe), and silicon carbide (SiC). For example, the third epitaxial layer 150C may be a germanium layer.

In some example embodiments (e.g., P-MOSFET), the first epitaxial layer 150A may include silicon germanium (SiGe) containing a first concentration of germanium (Ge), and the second epitaxial layer (150B) may include silicon germanium containing a second concentration of germanium (Ge) greater than the first concentration. For example, the first concentration of the first epitaxial layer 150A may be 20 atomic % or less, or 5 atomic % to 20 atomic %, and the second concentration of the second epitaxial layer 150B may be 30 atomic %, or from 30 atomic % to 60 atomic %. The first and second epitaxial layers 150A and 150B are doped with p-type impurities, and for example, the p-type impurities may include at least one of B, Al, Ga, and In.

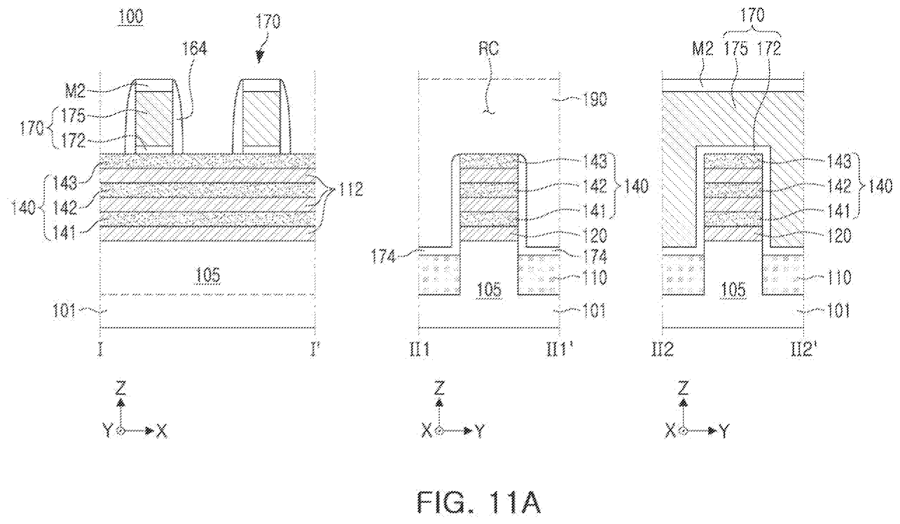

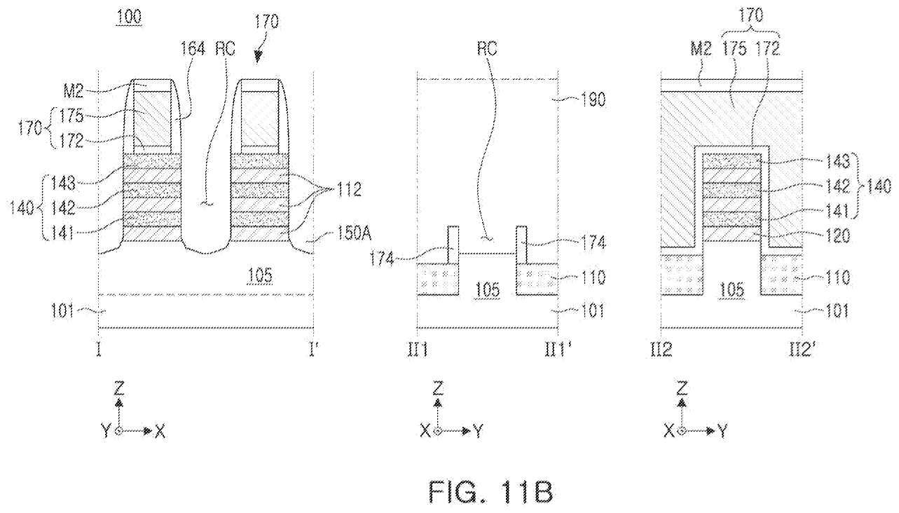

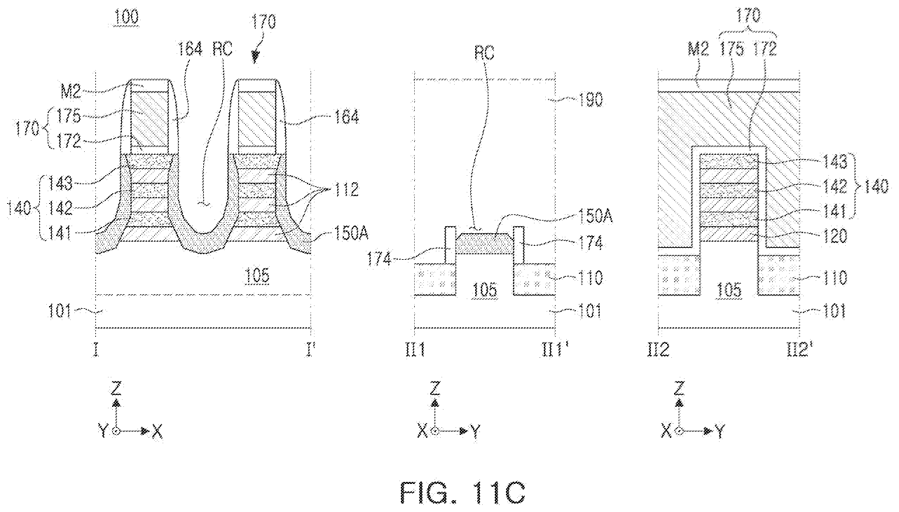

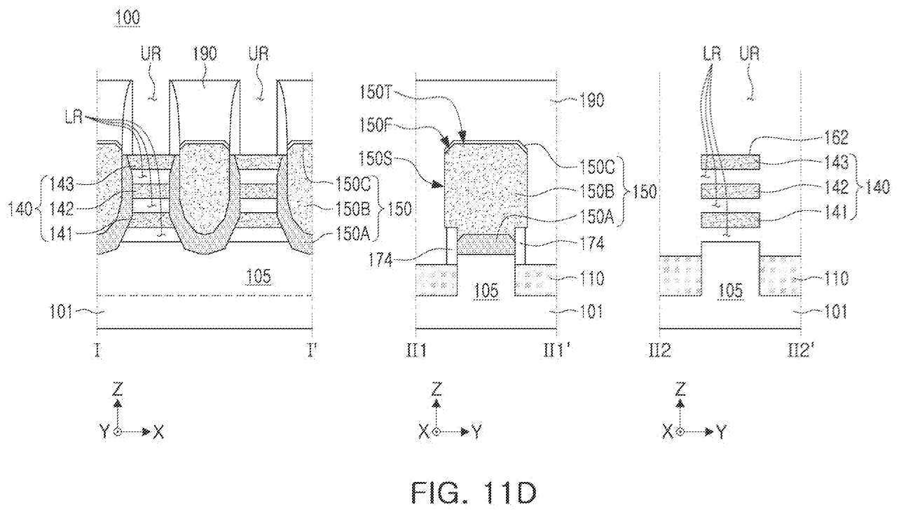

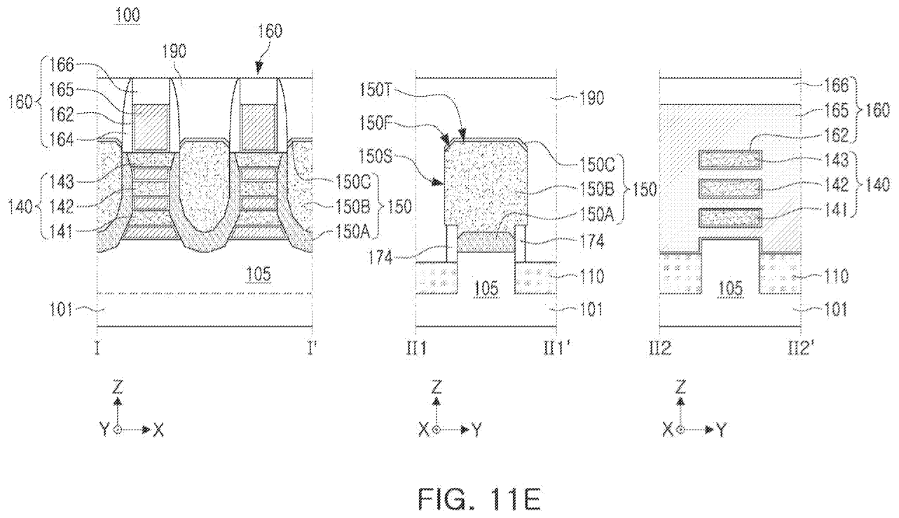

The first epitaxial layer 150A is formed on the top regions of the active pattern 105 on both sides of the gate structure 160 along the first direction (e.g., the X-direction) and the channel layers 141, 142, and 143, respectively. The first epitaxial layer 150A is formed on the side surfaces of the channel layers 141, 142, and 143 (see FIG. 11B).

As described above, because the upper surface of the substrate 101 has a (110) crystal plane rotated at 35.3° with respect to a vertical axis, the first to third channel layers grown on the upper surface (141, 142, 143) may have a predominantly (111) crystal plane. Accordingly, the first epitaxial layer 150A grown from the side surfaces of the first to third channel layers may be grown to have a substantially constant thickness in the first direction (e.g., the X-direction). The thickness is defined as a thickness of the first epitaxial layer 150A measured in the first direction.

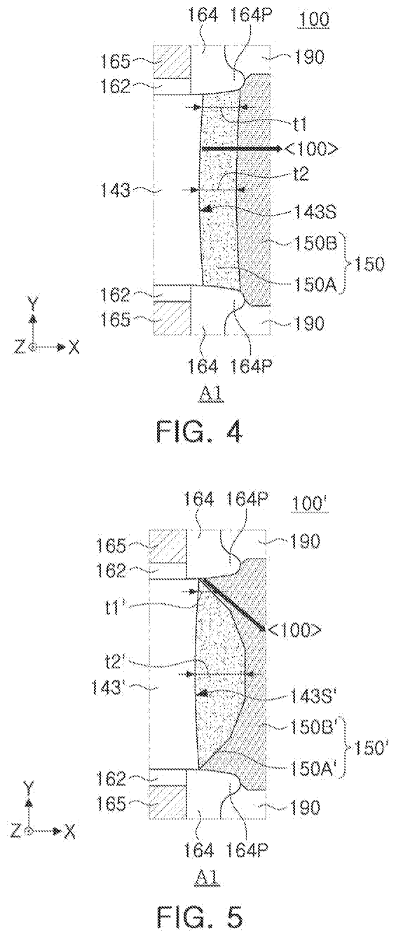

FIG. 4 is a partially enlarged view illustrating part “A1” of FIG. 1, and FIG. 5 is a substrate having an upper surface of a (100) crystal plane, unlike the semiconductor device 100 illustrated in FIG. 4. An area corresponding to FIG. 4 of the semiconductor device 100′ is illustrated.

Referring to FIG. 4, from a plan view, the source/drain region 150 is connected to the side surface 143S of the third channel layer 143 at the top, and the gate insulating layer 162 and the gate electrode 165 surrounding the third channel layer 143 are disposed on both sides of the third channel layer 143 and are spaced apart from each other in the Y-direction.

As mentioned above, because the side surface 143S of the third channel layer 143 has a (111) crystal plane, the first epitaxial layer 150A may be grown in a <100> crystal direction. The first epitaxial layer 150A grown in the <100> crystal direction may have an ideally constant thickness in the first direction (e.g., the X-direction). Even if this growth process is affected by an external factor (e.g., the state of the side surface 143S, etc.), the thickness t1 of the edge portion and the thickness t2 of the central portion of the first epitaxial layer 150A may include deviations that are less than 5%. As such, the first epitaxial layer 150A may be grown to have a substantially constant thickness in the first direction (e.g., the X-direction).

Referring to FIG. 4, the gate spacers 164 may have portions 164P protruding from the side surface 143S of the third channel layer 143 in the first direction (e.g., the X-direction). Because the edge portion of the first epitaxial layer 150A adjacent to the protruding portion 164P has a sufficient thickness t1, in the process of removing the sacrificial layer (see FIG. 11D), the first etching selectivity of the first epitaxial layer 150A with respect to the sacrificial layer is high. The source/drain region 150 (in particular, the second epitaxial layer 150B having a relatively low selectivity) may be protected by the epitaxial layer 150A.

As such, because the first epitaxial layer 150A is grown to have a substantially constant thickness in the first direction (e.g., the X-direction), the gate spacers 164 are formed by the edge portion of the first epitaxial layer 150A. The edge portion of the first epitaxial layer 150A may cover the inner sidewalls of the protruding parts 164P of the gate spacers 164. As a result, it is possible to prevent the source/drain regions 150 from being etched in the process of removing the sacrificial layer. Other side surfaces spaced apart from the side surface 143S of the third channel layer 143 in the first direction (e.g., the X-direction) may have a similar shape.

Unlike the semiconductor device 100 illustrated in FIG. 4, the semiconductor device 100′ illustrated in FIG. 5 may be understood as a product grown on an upper surface of a substrate, which is a (100) crystal plane of the substrate. Referring to FIG. 5, a side surface 143S′ of the uppermost third channel layer 143′ has a (110) crystal plane. Therefore, the first epitaxial layer 150A′ is grown in a <100> crystal direction (see arrow) according to the facet growth mode, and unlike the first epitaxial layer 150A discussed above, the first epitaxial layer 150A′ has a convex shape in the first direction (e.g., the X-direction). In the first epitaxial layer 150A′, the edge portion may have a thickness t1′ much smaller than the thickness t2′ of the central portion.

As such, because the edge portion of the first epitaxial layer 150A′ adjacent to the protruding portion 164P of the gate spacers 164 has a very thin thickness t1, in the sacrificial layer removal process (see FIG. 11D), a short may occur between the gate electrode 165 and the source/drain region 150′. Even if the first epitaxial layer 150A′ has a high etching selectivity with respect to the sacrificial layer in, because it is very thin, it is etched together with the sacrificial layer, and the source/drain region 150′ (particularly, the second epitaxial layer 150B′ having a relatively low selectivity) may be etched. A significant portion of the epitaxial layer 150B′ may be lost by etching. As a result, because the gate structure 160 may be formed as a missing region, a short may occur between the gate electrode 165 and the source/drain region 150′.

However, as illustrated in FIG. 4, the semiconductor device 100 has a first epitaxial layer 150A having a substantially constant thickness in the first direction (e.g., the X-direction), so that the protruding portion 164P may be covered by an edge portion of the first epitaxial layer 150A having a sufficient thickness. Accordingly, it is possible to effectively prevent the source/drain regions 150 from being etched in the process of removing the sacrificial layer.

Not only the side surface 143S of the third channel layer 143, but also the side surfaces of the other channel layers 141 and 142 have a (111) crystal plane, and similar to the structure illustrated in FIG. 4, when viewed from a plan view, a portion of the first epitaxial layer 150A located on the side of the first and second channel layers 141 and 142 may also have a substantially constant thickness in the first direction (e.g., the X-direction).

In addition, because the source/drain regions 150 are grown from side surfaces that are (111) crystal planes of the channel layers 141, 142, and 143, they may have unique crystal planes and unique structures. FIG. 3A shows a cross section of the source/drain region 150 cut in the second direction (e.g., the Y-direction).

Referring to FIG. 3A, the top surface (i.e., the upper surface) 150T of the source/drain region 150 is positioned parallel to the top surface of the substrate 101. The width of the lower portion of the source/drain region 150 may be defined by the spacing of the fence spacers 174. The fence spacers 174 are formed together with the gate spacers 164 on both sides of the gate structure 160, and remain when recess regions are formed in the fin structures on both sides of the gate structure 160.

As illustrated in FIG. 3A, a portion of the source/drain region 150 grown above the fence spacers 174 is a region grown to have a specific crystal plane, and may have a rectangular shape in which both upper corners are chamfered. In a cross section taken in the second direction (e.g., the Y-direction), the upper surface 150T of the source/drain region 150 is a (100) crystal plane, and the side surface 150S of the source/drain region 150 is (111) crystal plane, and the chamfered surface 150F may be a (211) crystal plane.

The first to third channel layers 141, 142, and 143 may have the same or similar width as the active pattern 105 in the second direction (e.g., the Y-direction), and the gate structure 160 (e.g., the X-direction) in the first direction (e.g., the X-direction). It is not limited thereto, and in some example embodiments, the widths of the first to third channel layers 141, 142, and 143 may be slightly different. For example, the widths of the first channel layer 141 and the third channel layer 143 may be greater than that of the second channel layer 142. Also, in some example embodiments, when viewed in a first direction (e.g., the X-direction) (see FIG. 2), the first to third channel layers 141, 142, and 143 may have a width smaller than that of a portion of the gate structure 160 positioned on the third channel layer 143.

The first to third channel layers 141, 142, and 143 may include a semiconductor material capable of providing a channel region. For example, the first to third channel layers 141, 142, and 143 may include at least one of silicon (Si), silicon germanium (SiGe), and germanium (Ge). The first to third channel layers 141, 142, and 143 may be formed of the same material as the substrate 101, for example. The number of channel layers 141, 142, and 143 is illustrated as three, but the number and shape may be variously changed.

As the number of channel layers 141, 142, and 143 increases, the aspect ratio of the source/drain region may increase. The aspect ratio of the source/drain region 150 can be relatively increased by introducing the three channel layers 141, 142, and 143. In a cross section in the first direction (e.g., the X-direction) (see FIG. 2), the aspect ratio of the source/drain region 150 may be 2 or more, and in some example embodiments may be 2.5 or more.

The first epitaxial layer 150A is grown from the bottom region located on the upper surface of the active pattern 105 and side surfaces of the first to third channel layers 141, 142, and 143 connected to the bottom region and merged with each other. It may have a side wall region. In some example embodiments, the thickness of the bottom region may be slightly greater than the thickness of the sidewall region. The second epitaxial layer 150B may have a slightly convex shape, but is not limited thereto.

As described above, the gate structure 160 may include a gate insulating layer 162, a gate electrode 165, gate spacers 164, and a gate capping layer 166.

As illustrated in FIG. 2, the gate insulating layer 162 may be disposed between the active pattern 105 and the gate electrode 165 and between the channel layers 141, 142, and 143 and the gate electrode 165. The gate insulating layer 162 may be formed to surround the channel layers 141, 142, and 143 in a second direction (e.g., the Y-direction), and may extend from the upper surface of the active pattern 105 to the upper surface of the device isolation layer 110 (see FIG. 3B). As illustrated in FIG. 2, the gate insulating layer 162 may extend between the gate electrode 165 and the gate spacers 164. For example, the gate insulating layer 162 may include an oxide, a nitride, or a high-κ material. The high-κ material may mean a dielectric material having a higher dielectric constant than silicon oxide (SiO₂). The high dielectric constant material may be at least one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrode 165 may fill a space between the plurality of channel layers 141, 142, and 143 from the top of the active pattern 105 and extend above the uppermost third channel layer 143. The gate electrode 165 may be spaced apart from the plurality of channel layers 141, 142, and 143 by the gate insulating layer 162. The gate electrode 165 may include a conductive material, for example, a metal nitride such as titanium nitride (TiN), tantalum nitride (TaN), or tungsten nitride (WN), or a metal material such as aluminum (Al), tungsten. (W) or molybdenum (Mo), or a semiconductor material such as doped polysilicon. In some example embodiments, the gate electrode 165 may be composed of two or more multi-layers. In some example embodiments, the gate electrode 165 may be disposed across adjacent transistors, and the gate electrode 165 may be separated by a separate separator located between adjacent transistors.

Gate spacers 164 may be disposed on both sides of the gate electrode 165. The gate spacers 164 may insulate the source/drain regions 150 and the gate electrodes 165 from each other. In some example embodiments, the gate spacers 164 may have a multi-layered structure. For example, the gate spacers 164 may include oxide, nitride, and oxynitride, and particularly may include a low dielectric constant layer. The fence spacers 174 may include the same material as the material of the gate spacers 164. The gate capping layer 166 may be disposed on the gate electrode 165 and may be surrounded by the gate electrode 165 and the gate spacers 164 on the bottom and side surfaces, respectively.

The semiconductor device 100 may further include contact structures 180 that pass through the interlayer insulating layer 190 and are connected to the source/drain regions 150. The second epitaxial layer 150B may be connected to the contact structure 180.

An electrical signal may be applied to the source/drain region 150 through the contact structure 180. The contact structure 180 may be disposed on the source/drain region 150 as illustrated in FIGS. 1 and 2. In some example embodiments, the contact structure 180 may be disposed to have a longer length than the source/drain region 150 along the second direction (e.g., the Y-direction). The contact structure 180 may have a structure in which the width of the lower portion is narrower than the width of the upper portion, but is not limited thereto. The contact structure 180 may horizontally overlap with, for example, the uppermost third channel layer 143. The contact structure 180 may extend to equal to or lower than a height corresponding to an upper surface of the third channel layer 143, which is a first higher level. In some example embodiments, the contact structure 180 may extend to a height corresponding to the upper surface of the second channel layer 142, which is a second higher level, for example. In other words, the contact structure 180 may have a lower surface, and a level PL of the lower surface may be located between the first higher level and the second higher level. For example, the contact structure 180 may include a metal nitride such as titanium nitride (TiN), tantalum nitride (TaN), or tungsten nitride (WN), and/or aluminum (Al), tungsten (W), or molybdenum (Mo).

The interlayer insulating layer 190 covers the source/drain regions 150 and the gate structures 160, and may be disposed to cover the device isolation layer 110 in some regions. For example, the interlayer insulating layer 190 may include at least one of oxide, nitride, and oxynitride, and may include a low-κ material.

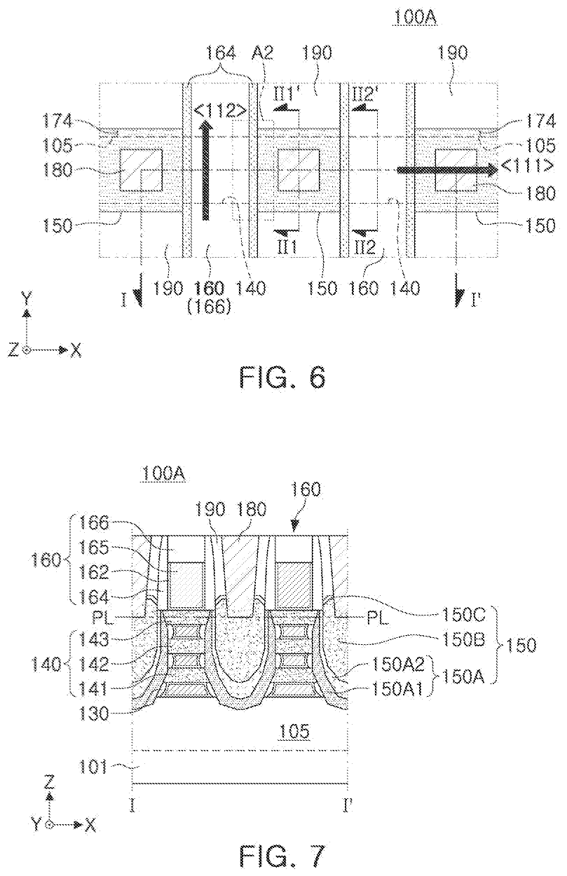

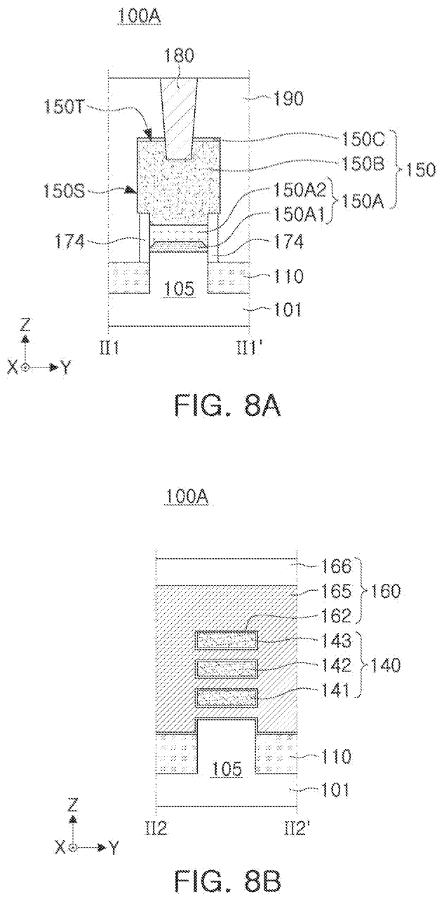

FIG. 6 is a plan view illustrating a semiconductor device according to an example embodiment, FIG. 7 is a cross-sectional view of the semiconductor device of FIG. 16 taken along line I-I′, and FIGS. 8A and 8B are cross-sectional views of the semiconductor device of FIG. 1 taken along lines II1-II1′ and II2-II2′, respectively.

Referring to FIGS. 6, 7, 8A, and 8B, the semiconductor device 100A has a top surface of a substrate 101 rotated by 45° with respect to an axis perpendicular to the top surface, a (100) crystal plane, and an intermediate epitaxial layer 150A2 is further included between the first epitaxial layer 150A1 and the second epitaxial layer 150B of the source/drain region 150. The semiconductor device 100A may be understood to be similar to the semiconductor device 100 illustrated in FIGS. 1 to 4 except that it further includes an internal spacer 130 and the intermediate epitaxial layer 150A2. In addition, elements may be understood with reference to descriptions of the same or similar elements of the semiconductor device 100 illustrated in FIGS. 1 to 4 unless otherwise stated.

The substrate 101 has a (100) crystal plane rotated by 45° with respect to an axis perpendicular to the upper surface thereof. As illustrated in FIG. 6, a first direction (e.g., the X-direction) in which the active pattern 105 extends may be a <111> crystal direction, and a second direction in which the gate structure 160 extends (e.g., the Y-direction) may be a <112> crystal direction.

Referring to FIGS. 7 and 8A, the source/drain region 150 may include a first epitaxial layer 150A1, a second epitaxial layer 150B on the first epitaxial layer 150A1, and an intermediate epitaxial layer 150A2 between the first epitaxial layer 150A1 and the second epitaxial layer 150B. The source/drain region 150 may further include a third epitaxial layer 150C on the second epitaxial layer 150B.

The first to third epitaxial layers 150A1, 150B, and 150C and the intermediate epitaxial layer 150A2 may have different compositions. For example, the first epitaxial layer 150A1, the intermediate epitaxial layer 150A2, and the second epitaxial layers 150B may include at least one of silicon (Si), silicon germanium (SiGe), and silicon carbide (SiC). For example, the third epitaxial layer 150C may be a germanium layer.

In some example embodiments (e.g., P-MOSFET), the first epitaxial layer 150A1 may include silicon germanium (SiGe) containing a first concentration of germanium (Ge), and the second epitaxial layer (150B) may include silicon germanium containing a second concentration of germanium (Ge) greater than the first concentration. The intermediate epitaxial layer 150A2 may include silicon germanium (SiGe) having an intermediate concentration of germanium (Ge) between the first concentration and the second concentration.

The first epitaxial layer 150A1 is formed on the top regions of the active pattern 105 and on respective side surfaces of the channel layers 141, 142, and 143, on both sides of the gate structure 160 in the first direction (e.g., the X-direction), and subsequently, an intermediate epitaxial layer 150A2 and a second epitaxial layer 150B may be sequentially formed on the first epitaxial layer 150A1.

As described above, because the upper surface of the substrate 101 has a (100) crystal plane rotated at 45° with respect to a vertical axis, the first to third channel layers grown on the upper surface (141, 142, 143) may have a predominantly (100) crystal plane. Accordingly, the first epitaxial layer 150A1 grown from the side surfaces of the first to third channel layers 141, 142, and 143 may be grown to have a substantially constant thickness in the first direction (e.g., the X-direction).

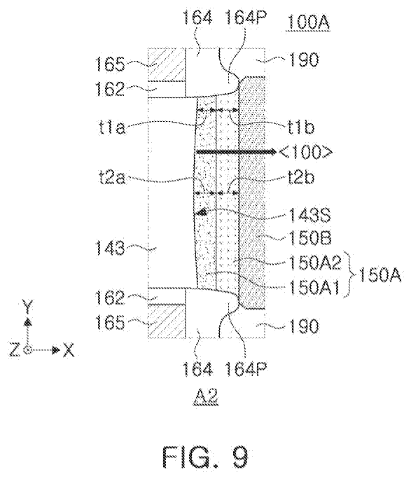

Referring to FIG. 9, from a plan view, the source/drain region 150 is connected to the side surface 143S of the third channel layer 143, which is the uppermost level, the gate insulating layer 162 and the gate electrode 165 surrounding the third channel layer 143 are disposed on both sides of the third channel layer 143 and are spaced apart from each other in the Y-direction.

As mentioned above, because the side surface 143S of the third channel layer 143 has a (100) crystal plane, the first epitaxial layer 150A1 and the intermediate epitaxial layer 150A2 each have a <100> crystal direction in which a crystal can grow. The first epitaxial layer 150A1 and the intermediate epitaxial layer 150A2 grown in the <100> crystal direction may have ideally constant thicknesses in the first direction (e.g., the X-direction). In some example embodiments, a deviation between the thicknesses t1a and t1b of the edge portion and the thicknesses t2a and t2b of the central portion of the first epitaxial layer 150A1 and the intermediate epitaxial layer 150A2 may be less than 5%. As such, the first epitaxial layer 150A1 may be grown to have a substantially constant thickness in the first direction (e.g., the X-direction). Similarly, the intermediate epitaxial layer 150A2 may be grown to have a substantially constant thickness in the first direction. (e.g., the X-direction).

Referring to FIG. 9, the gate spacers 164 may have portions 164P protruding from the side surface 143S of the third channel layer 143 in the first direction (e.g., the X-direction). Because the edge portion of the first epitaxial layer 150A1 adjacent to the protruding portion 164P has a sufficient thickness t1a, in the process of removing the sacrificial layer (see FIG. 11D), the first etching selectivity of the first epitaxial layer 150A1 with respect to the sacrificial layer is high. The source/drain region 150 (in particular, the second epitaxial layer 150B having a relatively low selectivity) may be protected by the epitaxial layer 150A1.

As such, because the first epitaxial layer 150A1 is grown to have a substantially constant thickness in the first direction (e.g., the X-direction), internal sidewalls of the protruding portions 164P of the gate spacers 164 may be covered by the edge portion of the first epitaxial layer 150A. Because the middle epitaxial layer 150A2 also has a relatively higher etch selectivity to the sacrificial layer than the second epitaxial layer 150B, similar to the first epitaxial layer 150A1, the source/drain region 150 may be protected during the sacrificial layer removal process.

In addition to the side surface 143S of the third channel layer 143, the side surfaces of the other channel layers 141 and 142 may also have a (100) crystal plane, and similar to the structure illustrated in FIG. 9, when viewed from a plan view, a portion of the first epitaxial layer 150A1 located on the side of the first and second channel layers 141 and 142 may also have a substantially constant thickness in the first direction (e.g., the X-direction).

Because the source/drain region 150 is grown from side surfaces that are (100) crystal planes of the channel layers 141, 142, and 143, it may have unique crystal planes and a unique structure. FIG. 8A shows a cross section of the source/drain region 150 cut in the second direction (e.g., the Y-direction).

Referring to FIG. 8A, the top surface 150T of the source/drain region 150 is positioned parallel to the top surface of the substrate 101. The width of the lower portion of the source/drain region 150 may be defined by the spacing of the fence spacers 174. A portion grown on the fence spacers 174 in the source/drain region 150 is a region grown to have a specific crystal plane and may have a rectangular shape. In a cross section taken in the second direction (e.g., the Y-direction), the upper surface 150T of the source/drain region 150 is a (100) crystal plane, and the side surface 150S of the source/drain region 150 is (100) may be a crystal plane.

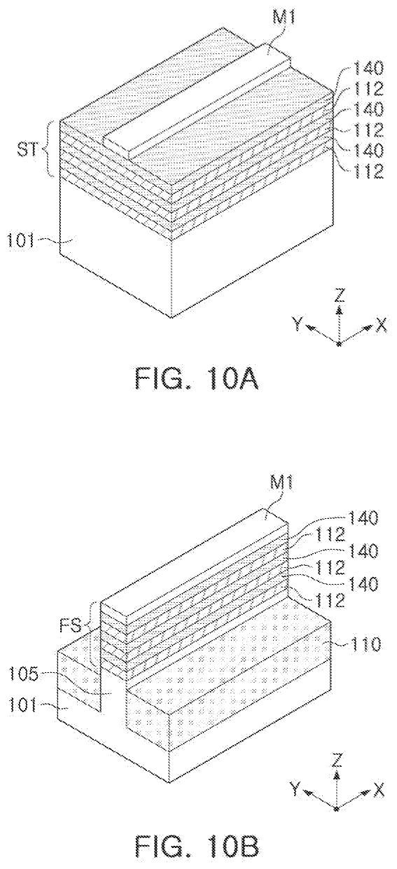

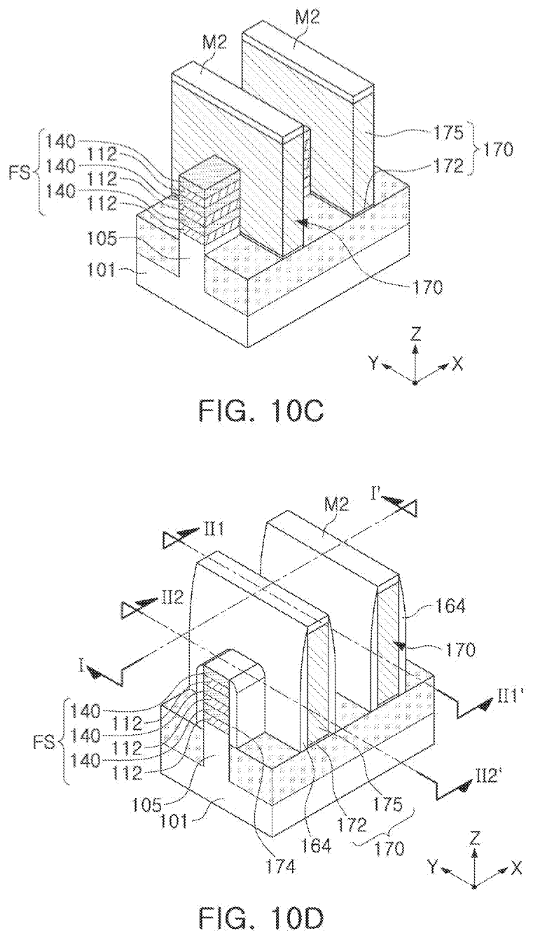

FIGS. 10A to 10D are perspective views illustrating some processes (forming a fin structure and a dummy gate) of a method of manufacturing a semiconductor device according to an example embodiment.

First, referring to FIG. 10A, a semiconductor stack ST is formed in which first semiconductor layers 112 and second semiconductor layers 140 are alternately stacked on a substrate 101.

The first semiconductor layers 112 may be removed in a subsequent process and used as a sacrificial layer, and the second semiconductor layers 140 may be used as a channel layer. The first semiconductor layers 112 and the second semiconductor layers 140 may include a semiconductor material including at least one of silicon (Si), silicon germanium (SiGe), and germanium (Ge), but different semiconductor materials may be used. The first semiconductor layers 112 may be formed of a material having a high etching selectivity with respect to the second semiconductor layers 140. The second semiconductor layers 140 may include impurities, but are not limited thereto. In some example embodiments, the first semiconductor layers 112 may include silicon germanium (SiGe), and the second semiconductor layers 140 may include silicon (Si). The first semiconductor layers 112 and the second semiconductor layers 140 may be grown on the substrate 101 through an epitaxial growth process. Each of the first semiconductor layers 112 and the second semiconductor layers 140 may have a thickness ranging from about 1 nm to about 100 nm.

In some example embodiments, when the substrate 101 has a (110) crystal plane rotated by 35.3° with respect to an axis perpendicular to the top surface, side surfaces of the first semiconductor layers 112 and the second semiconductor layers 140 may be spaced apart along the first direction (e.g., the X-direction) and may be a (111) crystal plane. In other example embodiments, when the substrate 101 has a (100) crystal plane rotated by 45° with respect to an axis perpendicular to the top surface, side surfaces of the first semiconductor layers 112 and the second semiconductor layers 140 spaced apart along the first direction (e.g., the X-direction) may be (100) crystal planes.

Subsequently, referring to FIG. 10B, an active structure is formed by removing portions of the semiconductor laminate ST and the substrate 101 using the first mask pattern M1 extending in a first direction (e.g., the X-direction).

The active structure may include the active pattern 105 and the fin structure FS. The active pattern includes a structure protruding from the upper surface of the substrate 101, which may be formed by removing a portion of the substrate 101, and the fin structure FS may include first semiconductor layers 112 and second semiconductor layers 140 that are alternately stacked on the active pattern 105 and patterned. The active pattern 105 and the fin structure FS may be formed in a line shape extending in one direction, for example, a first direction (e.g., an X-direction). In some example embodiments, when the substrate 101 has a (110) crystal plane rotated by 35.3° with respect to an axis perpendicular to the top surface, the first direction in which the fin structure FS extends may be a <111> crystal direction. In other example embodiments, when the substrate 101 has a (100) crystal plane rotated by 45° with respect to an axis perpendicular to the top surface, the first direction in which the fin structure FS extends may be a <100> crystal direction.

In the region where a part of the substrate 101 is removed, the device isolation layer 110 may be formed by filling an insulating material and then etching-back so that a part of the active pattern 105 protrudes. For example, the upper surface of the device isolation layer 110 may be etched back lower than the upper surface of the active pattern 105.

Next, referring to FIG. 10C, sacrificial gate structures 170 extending in the second direction may be formed to intersect a partial region of the active structure.

The sacrificial gate structures 170 may be a sacrificial structure formed in a region where the gate insulating layer 162 and the gate electrode 165 are disposed above the first to third channel layers 141, 142, and 143 illustrated in FIG. 2 through a subsequent process. The sacrificial gate structures 170 have a line shape extending in a second direction (e.g., the Y-direction) crossing the active structures, and may be arranged to be spaced apart from each other in a first direction (e.g., the X-direction). After forming the first and second sacrificial gate layers 172 and 175 sequentially stacked on the substrate 101 (in particular, the device isolation layer 110) on which the active structure is formed, sacrificial gate structures 170 may be formed by patterning the laminated body using the second mask pattern M2 as illustrated in FIG. 10C.

The first and second sacrificial gate layers 172 and 175 may be an insulating layer and a conductive layer, respectively, but are not limited thereto, and the first and second sacrificial gate layers 172 and 175 may be formed of one layer. In some example embodiments, the first sacrificial gate layer 172 may include silicon oxide, and the second sacrificial gate layer 175 may include polysilicon. The second mask pattern M2 may include silicon oxide and/or silicon nitride.

Next, referring to FIG. 10D, gate spacers 164 and fence spacers 174 may be formed on both sides of the sacrificial gate structures 170 and both sides of the active structure, respectively.

After the spacer material layer is conformally formed on the sacrificial gate structure 170 and the active structure, anisotropic etching is applied to form the gate spacers 164 on both sides of the sacrificial gate structures 170. Fence spacers 174 may be formed on side surfaces, for example, both sides of the active pattern 105 and the fin structure FS. Both side surfaces on which the gate spacers 164 are formed are facing side surfaces of the sacrificial gate structures 170 in the first direction (e.g., the X-direction). Both side surfaces on which the fence spacers 174 are formed may be facing sides located in the second direction (e.g., the Y-direction) of the active structure. Also, the gate spacers 164 and the fence spacers 174 may be formed of the same material. The spacer material layer, for example, the gate spacers 164 and the fence spacers 174 may be formed of a low-κ material, and for example, may include at least one of SiO, SiN, SiCN, SiOC, SiON, and SiOCN.

FIGS. 11A to 11E are cross-sectional views for explaining part of a method of manufacturing a semiconductor device (formation of source/drain and gate structures) according to an example embodiment.

Referring to FIG. 11A, cross-sections of the semiconductor structure of FIG. 10D taken along the line I-I′ and cross-sections taken along the lines II1-II1′ and II2-II2′ of the semiconductor structure of FIG. 10D are illustrated. Here, the sacrificial layers 120 may correspond to the patterned first semiconductor layers 112 illustrated in FIGS. 10B and 11A, and the channel layers 141, 142, and 143 may correspond to the patterned second semiconductor layers 140 illustrated in FIGS. 10B and 11A.

Next, referring to FIG. 11B, a recess RC may be formed by removing some regions of the fin structure FS located on both sides of the sacrificial gate structures 170. The sacrificial layers 120 and the channel layers 141, 142, and 143 are exposed through the recess RC.

The exposed sacrificial layers 120 and the exposed channel layers 141, 142, and 143 may be removed by using the second mask pattern M2 and the gate spacers 164 as a mask. Through this process, the lengths of the channel layers 141, 142, and 143 along the first direction (e.g., the X-direction) may be determined. Below the sacrificial gate structures 170, the sacrificial layers 120 and the channel layers 141, 142, and 143 are partially removed from the side surfaces so that both side surfaces of the remaining sacrificial layers 120 and channel layers 141, 142, and 143 along the first direction (e.g., the X-direction) may be located below the sacrificial gate structures 170 and the gate spacers 164. Also, after this process, fence spacers 174 located on both sides of the active structure may remain. In the process of removing the exposed portions of the sacrificial layers 120 and the channel layers 141, 142, and 143, a portion of the fence spacers 174 may also be lost. Accordingly, the height of the final fence spacers 174 may be determined. For example, in a cross section in the first direction (e.g., the X-direction), the aspect ratio of the recess RC formed in the present process may be 2.5 or more in the cross section in the first direction.

Next, referring to FIG. 11C, a first epitaxial layer 150A for forming source/drain regions may be formed in the recesses RC located on both sides of the sacrificial gate structures 170.

The first epitaxial layer 150A may include silicon germanium (SiGe). The first concentration of germanium (Ge) in the first epitaxial layer 150A may be 5 atomic % to 20 atomic %. The first epitaxial layer 150A may be grown from a top region of the active pattern 105, which is a bottom surface of the recess region RC, and side surfaces of the channel layers 141, 142, and 143.

In some example embodiments, when the substrate 101 has a (110) crystal plane rotated by 35.3° with respect to an axis perpendicular to the top surface, each of the side surfaces of the channel layers 141, 142, and 143 is a (111) crystal plane, and the first epitaxial layer 150A may be grown on each of the side surfaces in a <111> crystal direction. In other example embodiments, when the substrate 101 has a (100) crystal plane rotated by 45° with respect to an axis perpendicular to the top surface, each of the side surfaces of the channel layers 141, 142, and 143 is a (100) crystal plane, and the first epitaxial layer 150A may be grown on each of the side surfaces in a <100> crystal direction.

A portion of the first epitaxial layer 150A positioned on side surfaces of the plurality of channel layers 141, 142, and 143 may have a substantially constant thickness in the first direction when viewed from a plan view (see FIGS. 4 and 9). Portions of the first epitaxial layer 150A grown from side surfaces of the adjacent channel layers 141, 142, and 143 may be merged with each other so that the first epitaxial layer 150A may be continuously grown along the sidewall of the recess RC. Such growth conditions may be obtained by adjusting, for example, growth pressure, growth temperature, and/or gas flow rate.

Subsequently, referring to FIG. 11D, a source/drain region 150 is formed by growing a second epitaxial layer 150B and a third epitaxial layer 150C on the first epitaxial layer 150A, and then, the interlayer insulating layer 190 may be formed, and the sacrificial layers 120 and the sacrificial gate structures 170 may be removed to form upper gap regions UR and lower gap regions LR.

The second epitaxial layer 150B may be grown from the first epitaxial layer 150A using a selective epitaxial growth (SEG) process. The second epitaxial layer 150B may include silicon germanium having a second Ge concentration greater than the first Ge concentration of the first epitaxial layer 150A.

The interlayer insulating layer 190 may be formed by forming an insulating film covering the sacrificial gate structures 170 and the source/drain regions 150 and performing a planarization process. The sacrificial layers 120 and the sacrificial gate structure 170 may be selectively removed with respect to the gate spacers 164, the interlayer insulating layer 190, and the channel layers 141, 142, and 143. First, after forming the upper gap regions UR by removing the sacrificial gate structures 170 together with the second mask pattern M2, the sacrificial layers 120 exposed through the upper gap regions UR may be removed to form lower gap regions LR. For example, when the sacrificial layers 120 include silicon germanium (SiGe) and the second semiconductor layers 140 include silicon (Si), the sacrificial layers 120 are etched with peracetic acid and may be selectively removed by performing a wet etching process. During this removal process, the source/drain regions 150 may be protected by the interlayer insulating layer 190.

Subsequently, referring to FIG. 11E, gate structures 160 may be formed in the upper gap regions UR and the lower gap regions LR.

The gate insulating layer 162 may be formed to conformally cover inner surfaces of the upper gap regions UR and the lower gap regions LR. The gate electrodes 165 may be formed to completely fill the upper gap regions UR and the lower gap regions LR, and then may be removed from the top to a predetermined depth in the upper gap regions UR. A gate capping layer 166 may be formed in a region from which the gate electrodes 165 are removed in the upper gap regions UR. Through these processes, gate structures 160 including a gate insulating layer 162, a gate electrode 165, gate spacers 164, and a gate capping layer 166 may be formed.

Next, the semiconductor device 100 illustrated in FIGS. 2 to 3B may be manufactured by forming a contact structure 180 passing through the interlayer insulating layer 190 and connected to the source/drain region 150. A contact hole connected to the source/drain region 150 may be formed to pass through the interlayer insulating layer 190, and a conductive material may be filled in the contact hole to form the contact structure 180. The lower surface of the contact hole may be recessed into the source/drain regions 150 or may have a curve along the upper surface of the source/drain regions 150.

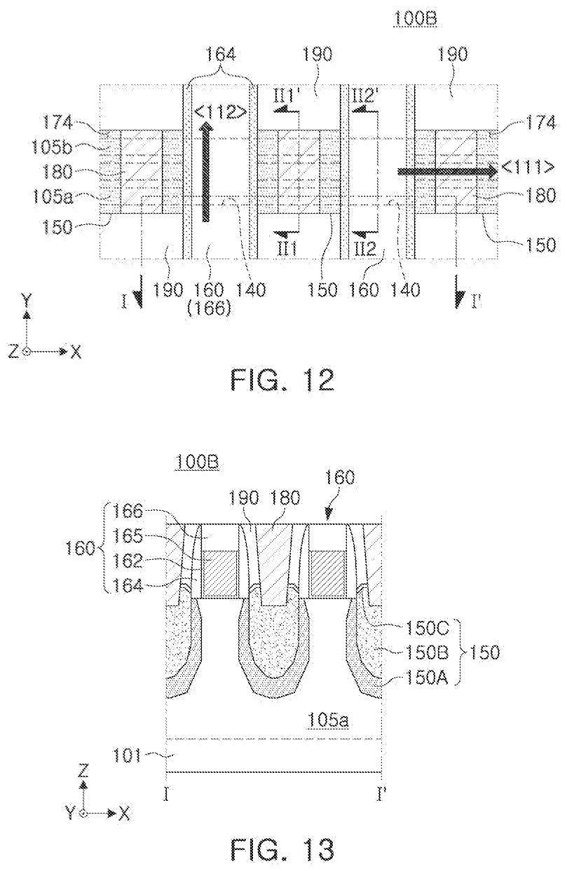

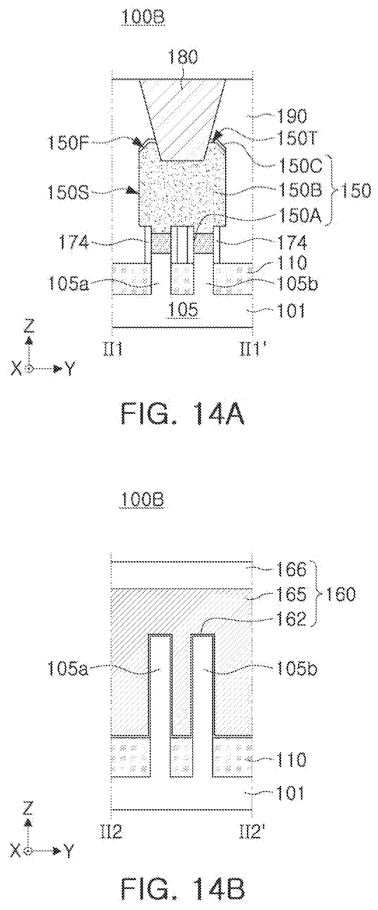

FIG. 12 is a plan view illustrating a semiconductor device according to an example embodiment, FIG. 13 is a cross-sectional view of the semiconductor device of FIG. 12 taken along line I-I′, and FIGS. 14A and 14B are cross-sectional views of the semiconductor device of FIG. 12 taken along lines II1-II1′ and II2-II2′, respectively.

Referring to FIGS. 12, 13, 14A, and 14B, semiconductor device 100B is provided with two active fins 105a and 105b. Elements may be understood with reference to descriptions of the same or similar elements of the semiconductor device 100 illustrated in FIGS. 1 to 3B unless otherwise stated.

As shown, the channel region may include two active fins 105a and 105b. The first and second active fins 105a and 105b each have a structure protruding from the upper surface of the substrate 101 upward (e.g., in the Z-direction) and may extend in a first direction (e.g., in the X-direction). As illustrated in FIGS. 14A and 14B, the first and second active fins 105a and 105b may be arranged side by side in the second direction (e.g., the Y-direction) on the substrate 101. In example embodiments, two active fins 105a and 105b arranged adjacently provide a channel region for one transistor. As illustrated, the first and second active fins 105a and 105b are exemplified as being provided by two, but example embodiments are not limited thereto, and may be provided singly or in other plural numbers.

Referring to FIGS. 12, 13 and 14A and 14B, the semiconductor device 100B includes a source/drain region 150 formed across two active fins 105a and 105b, and a source/drain region 150 may include contact structures 180 respectively connected to each other.

The semiconductor device 100B may include a gate structure 160 overlapping a region of each of the first and second active fins 105a and 105b and extending in the second direction (e.g., the Y-direction). The gate structure 160 may include gate spacers 164, a gate insulating layer 162, a gate electrode 165, and a gate capping layer 166.

The upper surface of the substrate 101 has a (110) crystal plane rotated by 35.3° with respect to an axis perpendicular to the upper surface. In example embodiments, as illustrated in FIG. 12, the first direction (e.g., the X-direction) in which the first and second active fins 105a and 105b extend may be a <111> crystal direction, and the second direction (e.g., the Y-direction) in which the gate structure (160) extend may be a <112> crystal direction.

Referring to FIGS. 13 and 14A, the source/drain region 150 may include a first epitaxial layer 150A and a second epitaxial layer 150B on the first epitaxial layer 150A. The first epitaxial layer 150A may include silicon germanium (SiGe) containing germanium (Ge) at a first concentration, and the second epitaxial layer 150B may include silicon germanium containing germanium (Ge) of a second concentration greater than the first concentration.

As described above, because the upper surface of the substrate 101 has a (110) crystal plane rotated at 35.3° with respect to a vertical axis, the first to third channel layers grown on the upper surface (141, 142, 143) may have a predominantly (111) crystal plane. Accordingly, the first epitaxial layer 150A grown from the side surface may be grown to have a substantially constant thickness in the first direction (e.g., the X-direction).

As such, because the weak edge portion of the first epitaxial layer 150A also has a sufficient thickness, the sacrificial layer is removed by the first epitaxial layer 150A having a high etching selectivity with respect to the sacrificial layer in the process of removing the sacrificial layer (see FIG. 11D). The source/drain regions 150 (in particular, the second epitaxial layer 150B having a relatively low selectivity) can be protected.

As set forth above, according to example embodiments, by appropriately selecting the crystal plane of the side of the channel region (e.g., channel layer), the epitaxial layer for the source/drain regions may be grown on the side, to have a constant thickness in the first direction (e.g., the X-direction). As a result, because the sacrificial layer and the first epitaxial layer having a high etching ratio can stably cover the weak region adjacent to the spacer, in the process of removing the sacrificial layer, a short between the gate electrode and the source/drain region may be effectively prevented. The crystal plane of the side of the channel region may be determined by the growth plane of the substrate.

While aspects of example embodiments have been illustrated and described above, it will be apparent to those skilled in the art that modifications and variations could be made without departing from the scope of the present inventive concept as defined by the appended claims.

1. A semiconductor device comprising:
a substrate;
an active pattern extending in a first direction on the substrate;
a plurality of channel layers arranged on the active pattern and spaced apart from each other in a vertical direction perpendicular to an upper surface of the substrate;
a gate structure crossing the active pattern, and surrounding the plurality of channel layers, the gate structure extending in a second direction that crosses the first direction; and
source/drain regions provided on the active pattern on both sides of the gate structure, and comprising a first epitaxial layer connected to each of side surfaces of the plurality of channel layers, and a second epitaxial layer provided on the first epitaxial layer and having a composition different from that of the first epitaxial layer,
wherein each of the side surfaces of the plurality of channel layers has a crystal plane of (111) or (100), and
wherein the first epitaxial layer extends in the second direction and has a first thickness in the first direction that is substantially constant.

2. The semiconductor device of claim 1, wherein each of the first epitaxial layer and the second epitaxial layer comprises silicon germanium (SiGe),
wherein the first epitaxial layer has a first concentration of germanium (Ge),
the second epitaxial layer has a second concentration of germanium (Ge) that is greater than the first concentration of germanium (Ge).

3. (canceled)

4. The semiconductor device of claim 2, wherein the source/drain regions further comprises a middle epitaxial layer that comprises silicon germanium and is provided between the first epitaxial layer and the second epitaxial layer, and
wherein a third concentration of germanium (Ge) in the middle epitaxial layer is higher than the first concentration and lower than the second concentration.

5. The semiconductor device of claim 4, wherein the middle epitaxial layer extends in the second direction on a side surface of an uppermost channel layer, among the plurality of channel layers, and has a second thickness in the first direction that is substantially constant.

6. The semiconductor device of claim 1, wherein the upper surface of the substrate is a (110) crystal plane rotated by 35.3° with respect to an axis perpendicular to the upper surface.

7. The semiconductor device of claim 6, wherein a cross section of a source/drain region, among the source/drain regions, in the second direction has a rectangular shape in which both upper corners are chamfered and form a chamfered surface.

8. The semiconductor device of claim 7, wherein in the cross section in the second direction, a top surface of the source/drain region is a (100) crystal plane, a side surface of the source/drain region is a (111) crystal plane, and the chamfered surface is a (211) crystal plane.

9. The semiconductor device of claim 1, wherein the upper surface of the substrate is a (100) crystal plane rotated by 45° with respect to an axis perpendicular to the upper surface.

10. The semiconductor device of claim 9, wherein a cross section of a source/drain region, among the source/drain regions, in the second direction has a rectangular shape with an upper side that is parallel to the upper surface of the substrate.

11. The semiconductor device of claim 10, wherein in the cross section in the second direction, a top surface of the source/drain region is a (100) crystal plane, and a side surface of the source/drain region is a (100) crystal plane.

12. The semiconductor device of claim 1, wherein the gate structure comprises a gate electrode crossing the active pattern, surrounding the plurality of channel layers, and extending along the second direction, and gate spacers located on both side surfaces of the gate electrode extending along the second direction.

13. The semiconductor device of claim 12, wherein the gate spacers have portions protruding in the second direction from both side surfaces of the plurality of channel layers along the first direction, and
wherein the first epitaxial layer covers inner sidewalls of protruding portions of the gate spacers.

14. (canceled)

15. A semiconductor device comprising:
a substrate;
a semiconductor channel on the substrate, the semiconductor channel having first and second side surfaces spaced apart from each other in a first direction, and third and fourth side surfaces spaced apart in a second direction that crosses the first direction;
first and second source/drain regions respectively provided on the first and second side surfaces of the semiconductor channel; and
a gate structure surrounding an upper surface and the third and fourth side surfaces of the semiconductor channel and extending in the second direction,
wherein each of the first and second source/drain regions comprises a first epitaxial layer provided on the first and second side surfaces of the semiconductor channel and a second epitaxial layer provided on the first epitaxial layer and having a composition different from that of the first epitaxial layer,
the first epitaxial layer extends in the second direction and has a first thickness in the first direction that is substantially constant, and
wherein a cross section of each of the first and second source/drain regions along the second direction has a rectangular shape.

16. (canceled)

17. The semiconductor device of claim 15, wherein the semiconductor channel comprises an active pattern that protrudes from the upper surface of the substrate and extends in the first direction, and a plurality of channel layers stacked on the active pattern and spaced apart from each other in a direction perpendicular to the upper surface of the substrate.

18. The semiconductor device of claim 15, wherein in the cross section along the second direction, each of the first and second source/drain regions has a top surface that is a (100) crystal plane and a side surface that is a (100) crystal plane.

19. The semiconductor device of claim 15, wherein a top surface of the substrate is a (110) crystal plane rotated at 35.3° with respect to an axis perpendicular to the top surface, and the first and second side surfaces of the semiconductor channel each have a (111) crystal plane.

20. The semiconductor device of claim 15, wherein the cross section of each of the first and second source/drain regions has the rectangular shape in which both upper corners are chamfered to form a chamfered surface.

21. The semiconductor device of claim 20, wherein in the cross section along the second direction, each of the first and second source/drain regions has a top surface that is a (100) crystal plane and a side surface that is a (111) crystal plane, and the chamfered surface is a (211) crystal plane.

22. The semiconductor device of claim 15, wherein a top surface of the substrate is a (100) crystal plane rotated by 45° about an axis perpendicular to the top surface, and the first and second side surfaces of the semiconductor channel each has a (100) crystal plane.

23. A semiconductor device comprising:
a substrate having an upper surface that is a (110) crystal plane;
a semiconductor channel on the substrate, the semiconductor channel having first and second side surfaces spaced apart from each other in a first direction, and third and fourth side surfaces spaced apart in a second direction that crosses the first direction;
first and second source/drain regions respectively provided on the first and second side surfaces of the semiconductor channel, each of the first side and the second side of the semiconductor channel having a (111) crystal plane; and
a gate structure surrounding an upper surface and the third and fourth side surfaces of the semiconductor channel, and extending in the second direction, the second direction of the substrate corresponding to a <112> crystal direction.

24. (canceled)
